(19) United States
(12) Patent Application Publication
(10) Pub. No.: US 2024/0396558 A1
(43) Pub. Date: Nov. 28, 2024

(54) TIMER CIRCUIT AND METHOD FOR PROVIDING ADJUSTABLE FREQUENCY TIMING IN A CLOSED-LOOP CONTROL CIRCUIT

(71) Applicant: Huawei Digital Power Technologies Co., Ltd., Shenzhen (CN)

(72) Inventor: Mattias Andersson, Kista (SE)

(21) Appl. No.: 18/798,327

(22) Filed: Aug. 8, 2024

Related U.S. Application Data
(63) Continuation of application No. PCT/EP2022/053233, filed on Feb. 10, 2022.

(51) Int. Cl. H03K 21/02; G06F 7/50

(52) U.S. Cl. CPC H03K 21/02; G06F 7/50

(57) ABSTRACT

A timer circuit is configured for providing adjustable frequency timing in a closed-loop control circuit. The timer circuit includes a period register, a counter, and a comparator. The period register is configured to hold a period value. The comparator is configured to determine when the counter reaches the period value. The timer circuit is configured to adjust the frequency by adjusting an increment controlling the counter.

### CROSS-REFERENCE TO RELATED APPLICATIONS

This application is a continuation of International Application No. PCT/EP2022/053233, filed on Feb. 10, 2022, the disclosure of which is hereby incorporated by reference in its entirety.

### FIELD

The disclosure relates generally to controlling a frequency in a closed-loop control circuit, and more particularly, the disclosure relates to a timer circuit and a method for providing adjustable frequency timing in the closed-loop control circuit. Moreover, the disclosure also relates to a controller having the timer circuit configured to vary a frequency (i.e. a frequency of a control object) of a control-loop, and a digital control mode switch controller configured to switch the mode of power supplies.

### BACKGROUND

A switch-mode power supply is a power converter that utilizes switching devices (e.g. metal-oxide-semiconductor field-effect transistor, MOSFETs) that continuously turn on and off at high frequency. Particularly, in a closed-loop control resonant power topology circuit (e.g. LLC, Resonant-Dual Action Bridge (DAB)), the switch frequency is varied to control the circuit. In any closed-loop control circuit, the loop delay or latency may affect the performance of the circuit. Delay may reduce the achievable bandwidth of the control circuit. This may have a negative impact on dynamic performance such as load steps or input voltage step of the circuit.

It is common to use microcontrollers to drive and control the switch-mode power supply. The microcontroller typically uses an analog-to-digital converter (ADC) to sample currents and voltages in the power supply and a timer circuit to generate command signals for switches in a power circuit.

Existing microcontrollers (e.g. TMS320F280049 from Texas instruments and STM32G474CBT from ST Microelectronics) or digital signal processors (DSPs) typically has digitally controlled oscillator (DCO) capabilities suitable for switch mode power control. These microcontrollers have peripheral timer circuits for the generation of the command signals for the power circuit.

The timer circuits commonly have a counter and a period register. The counter increments with one every clock cycle until it reaches a count value set by the period register when it resets to zero, referred to as up-count mode. The counter may also be configured to work in up-down-count mode. In the up-down-count mode, the counter increments with one until it reaches the count value set by the period register, then the count direction changes, and the counter decrements with one every clock cycle until it reaches zero. Thereafter, the counter again changes its count direction and starts to increment. The switching frequency is typically controlled by varying the period register. The disadvantage with these timer circuits is that a period value must be set before the start of a count cycle and it remains fixed during one count cycle.

The command signals are generated from the counter using digital comparators. Some existing timer circuits typically have fixed comparators at zero, and the period values and adjustable compare registers. When a comparison occurs, the command signal can be set high or low or toggle depending on the configuration of the timer circuit.

When using the microcontroller, especially proportional integral (PI) controller that sets the period for the digitally controlled oscillator (DCO), it often runs in an interrupt. This interrupt can be synchronized with the frequency of the DCO, but more commonly the interrupt runs at a fixed frequency. This adds more delay to the closed-loop control circuit. Further, all the existing timer circuits typically use a fixed counter increment of one.

A problem with the existing solutions is that a change of the period register typically takes effect only when a new switch period starts, that is when the counter reaches zero. This incurs extra delay in the control loop of the closed-loop control circuit. Delays in the control loop degrade dynamic performance of the power supply. It is possible to configure the timer circuit such that a write to the period register takes effect immediately, but this mode cannot be used as it may generate corrupt periods. For example, the period register has been previously set to 100 and the counter is at 90 and is counting up. A write to the period register occurs and it is set to 80 and it takes effect immediately. Since the counter has already passed 80, no period match occurs and the counter counts until its maximum count and completes the count cycle. This yields a switching period that is much too long and most likely damages the power circuit. When the timer circuit is configured in up-down-count mode, and the counter is decrementing, the change in the period register has no effect.

Therefore, there arises a need to address the aforementioned technical problem/drawbacks in controlling a frequency in switch-mode power supply.

### SUMMARY

The present disclosure provides a timer circuit and a method for providing adjustable frequency timing in a closed-loop control circuit. Moreover, the present disclosure provides a controller having the timer circuit configured to vary a frequency of a control-loop, and a digital control mode switch controller configured to switch the mode of power supplies while avoiding one or more disadvantages of prior art approaches.

The present disclosure provides a timer circuit and a method for providing adjustable frequency timing in a closed-loop control circuit. Moreover, the present disclosure provides a controller having the timer circuit configured to vary a frequency of a control-loop, and a digital control mode switch controller configured to switch the mode of power supplies.

According to a first aspect, there is provided a timer circuit configured for providing adjustable frequency timing in a closed-loop control circuit. The timer circuit includes a period register, a counter, and a comparator. The period register is configured to hold a period value. The comparator is configured to determine when the counter reaches the period value. The timer circuit is configured to adjust the frequency by adjusting an increment controlling the counter.

The timer circuit reduces a delay in closed-loop operations of the closed-loop control circuit as a count period (i.e. a period time that corresponds to the frequency) can be changed mid-period, thereby eliminating the need to wait until a next counting period. The timer circuit eliminates the need for the period register to change the count period. The timer circuit reduces the delay incurred when varying the count period. The timer circuit improves the dynamic performance of the closed-loop control circuit by reducing the latency/delay in the closed-loop operations. The timer circuit uses a different method to control the count period of a count cycle. The period value is fixed and the count period is controlled by varying the increment. In the timer circuit, the increment varies between 0 and 1. If the timer circuit changes the increment during the count cycle, it takes effect immediately without a risk of a corrupt period. The timer circuit allows for over sampling, i.e. the timer circuit can change the increment multiple times during the count cycle, which makes control command information also effective multiple times even between the switching periods. The timer circuit uses a variable increment register to generate the count period for resonant power topology circuits in the closed-loop operation. The timer circuit can be used for all control loop circuits where a frequency is to be controlled.

In an embodiment, the timer circuit further includes an increment register for holding the increment. An adjustment of the increment adjusts the frequency of the timer circuit. The timer circuit may be configured to receive an adjusted increment value by the adjusted increment value being written to the increment register. In embodiments, the timer circuit further includes a residual register, and an adding circuit. The residual register is holding a residual. The adding circuit is connected to the increment register and the residual register. The adding circuit is configured to (i) generate a sum by adding the increment to the residual; (ii) determine if the sum is less than an overflow value (OV), and if so output the sum to the residual register, and if not enable the counter and output the remainder of the overflow value subtracted from the sum to the residual register.

In an embodiment, the increment (i) is in the range larger than zero and equal to or less than the overflow value, OV, (0<i<=OV). The residual register may be configured to be reset when the counter is reset. In embodiments, the increment is decimal, the overflow value is 1, and the increment is binary.

According to a second aspect, there is provided a controller configured to vary a frequency of a control-loop. The controller includes a timer circuit as described above.

The controller reduces a delay in closed-loop operations of the closed-loop control circuit as a count period (i.e. a period time that corresponds to the frequency) can be changed mid-period, thereby eliminating the need to wait until a next counting period. The controller improves the dynamic performance of the closed-loop control circuit by reducing the latency/delay in the closed-loop operations. The controller can be used for all control loop circuits where a frequency is to be controlled. The timer circuit uses a variable increment register to generate the count period for resonant power topology circuits in the closed-loop operation.

In an embodiment, the controller is configured to determine that the frequency is to be adjusted and in response thereto adjusting the increment.

According to a third aspect, there is provided a digital control mode switch controller configured to switch the mode of power supplies. The digital control mode switch controller includes a controller as described above.

The digital control mode switch controller reduces a delay in closed-loop operations of the closed-loop control circuit as a count period (i.e. a period time corresponds to the frequency) that can be changed mid-period, thereby eliminating the need to wait until a next counting period. The digital control mode switch controller improves the dynamic performance of the closed-loop control circuit by reducing the latency/delay in the closed-loop operations.

According to a fourth aspect, there is provided a method for providing adjustable frequency timing in a closed-loop control circuit. The method includes increasing a counter based on an increment. The method includes determining if the counter reaches a period value. The method adjusts the frequency by adjusting the increment.

The method of the present disclosure reduces a delay in closed-loop operations of the closed-loop control circuit as a count period that can be changed mid-period, thereby eliminating the need to wait until a next counting period. The method also eliminates the need for the period register to change the count period. The method reduces the delay incurred when varying the count period. The method improves the dynamic performance of the closed-loop control circuit by reducing the latency/delay in the closed-loop operations. The method controls the count period of a count cycle. The period value is fixed and the count period is controlled by varying the increment. If the method changes the increment during the count cycle, it takes effect immediately without a risk of a corrupt period. The method allows for over sampling, i.e. the method can change the increment multiple times during the count cycle, which makes control command information also effective multiple times even between the switching periods. The method uses a variable increment register to generate the count period for resonant power topology circuits in the closed loop operation. The method can be used for all control loop circuits where a frequency is to be controlled.

In an embodiment, the method further includes holding a residual in a residual register. The method further includes generating a sum by adding the increment to the residual. The method further includes determining if the sum is less than an overflow value (OV), and if so outputting the sum to the residual register, and if not increasing the counter and outputting the remainder of the overflow value subtracted from the sum to the residual register.

In an embodiment, the method further includes determining that the frequency is to be adjusted and in response thereto adjusting the increment.

Therefore, in contradiction to the existing solutions, the timer circuit reduces a delay in closed-loop operations of the closed-loop control circuit as a count period that can be changed mid-period, thereby eliminating the need to wait until a next counting period. The timer circuit eliminates the need for the period register to change the count period. The timer circuit improves the dynamic performance of the closed-loop control circuit by reducing the latency/delay in the closed-loop operations. The timer circuit uses a different method to control the count period of a count cycle. The period value is fixed and the count period is controlled by varying the increment. If the timer circuit changes the increment during the count cycle, it takes effect immediately without a risk of corrupt period. The timer circuit allows for over sampling, i.e. the timer circuit can change the increment multiple times during the count cycle, which makes control command information also effective multiple times even between the counting/switching periods.

These and other aspects of the disclosure will be apparent from the implementation(s) described below.

### BRIEF DESCRIPTION OF DRAWINGS

Implementations of the disclosure will now be described, by way of example only, with reference to the accompanying drawings, in which:

FIG. 1 illustrates an exploded view of a timer circuit for providing adjustable frequency timing in a closed-loop control circuit in accordance with an implementation of the disclosure;

FIG. 2 illustrates an exemplary view of a timer circuit having a shortest count period in a closed-loop control circuit in accordance with an implementation of the disclosure;

FIG. 3 illustrates an exemplary view of a timer circuit having a longest count period in a closed-loop control circuit in accordance with an implementation of the disclosure;

FIG. 4 is a block diagram of a controller to vary a frequency of a control-loop in accordance with an implementation of the disclosure;

FIG. 5 is a block diagram of a digital control mode switch controller to switch the mode of power supplies in accordance with an implementation of the disclosure;

FIG. 6 is a graphical representation that shows an effect of a timer circuit that reduces a control loop delay of a closed-loop control circuit in accordance with an implementation of the disclosure;

FIG. 7 is a graphical representation that shows an effect of a timer circuit that changes the increment multiple times during a count cycle in accordance with an implementation of the disclosure; and

FIG. 8 is a flow diagram that illustrates a method for providing adjustable frequency timing in a closed-loop control circuit in accordance with an implementation of the disclosure.

### DETAILED DESCRIPTION

Implementations of the present disclosure provide a timer circuit and a method for providing adjustable frequency timing in a closed-loop control circuit. Moreover, the present disclosure provides a controller having the timer circuit configured to vary a frequency of a control-loop, and a digital control mode switch controller configured to switch the mode of power supplies.

To make solutions of the present disclosure more comprehensible for a person skilled in the art, the following implementations of the disclosure are described with reference to the accompanying drawings.

Terms such as “a first,” “a second,” “a third,” and “a fourth” (if any) in the summary, claims, and foregoing accompanying drawings of the disclosure are used to distinguish between similar objects and are not necessarily used to describe a specific sequence or order. It should be understood that the terms so used are interchangeable under appropriate circumstances, so that the implementations of the disclosure described herein are, for example, capable of being implemented in sequences other than the sequences illustrated or described herein. Furthermore, the terms “include” and “have” and any variations thereof, are intended to cover a non-exclusive inclusion. For example, a process, a method, a system, a product, or a device that includes a series of steps or units, is not necessarily limited to expressly listed steps or units but may include other steps or units that are not expressly listed or that are inherent to such process, method, product, or device.

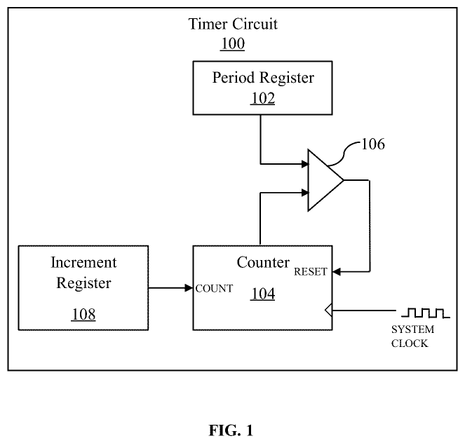

FIG. 1 illustrates an exploded view of a timer circuit 100 for providing adjustable frequency timing in a closed-loop control circuit in accordance with an implementation of the present disclosure. The timer circuit 100 includes a period register 102, a counter 104, and a comparator 106. The period register 102 is configured to hold a period value. The comparator 106 is configured to determine when the counter 104 reaches the period value. The timer circuit 100 is configured to adjust the frequency by adjusting an increment controlling the counter 104.

The timer circuit 100 reduces a delay in closed-loop operations of the closed-loop control circuit as a count period (i.e. a period time corresponds to the frequency) can be changed mid-period, thereby eliminating the need to wait until a next switching period. The timer circuit 100 eliminates the need for the period register 102 to change the count period. The timer circuit 100 reduces the delay incurred when varying the count period. The timer circuit 100 improves the dynamic performance of the closed-loop control circuit by reducing the latency/delay in the closed-loop operations. The timer circuit 100 uses a different method to control the count period of a count cycle. The period value is fixed and the count period is controlled by varying the increment. If the timer circuit 100 changes the increment during the count cycle, it takes effect immediately without a risk of a corrupt period. The timer circuit 100 allows for over sampling, i.e. the timer circuit 100 can change the increment multiple times during the count cycle, which makes control command information also effective multiple times even between the counting/switching periods. The timer circuit 100 uses a variable increment register to generate the count period for resonant power topology circuits in the closed-loop operation. The timer circuit 100 can be used for all control loop circuits where a frequency is to be controlled.

In an embodiment, the timer circuit 100 further includes an increment register 108 for holding the increment. An adjustment of the increment adjusts the frequency of the timer circuit 100. The timer circuit 100 may be configured to receive an adjusted increment value by the adjusted increment value being written to the increment register 108. In embodiments, the increment (i) is in the range larger than zero and equal to or less than an overflow value (OV), i.e. (0<i<=OV). In an embodiment, if the increment is equal to the overflow value, then the timer circuit 100 allows a highest frequency in the closed-loop control circuit. In embodiments, the increment is decimal, the overflow value is 1, and the increment may be binary.

In an embodiment, the period register 102 fixes the period value for maintaining a maximum frequency/minimum count period in the closed-loop control circuit. In embodiments, the period register 102 determines a match event (i.e. matching the period value with an integer of the counter 104), which triggers the counter 104 to reset to zero when the counter 104 reaches the period value. The increment may be changed several times during the count period/a count cycle. In the timer circuit 100, the increment varies between 0 and 1. The increment may include an integer and a decimal. The counter 104 and the increment both may have the integer and the decimal.

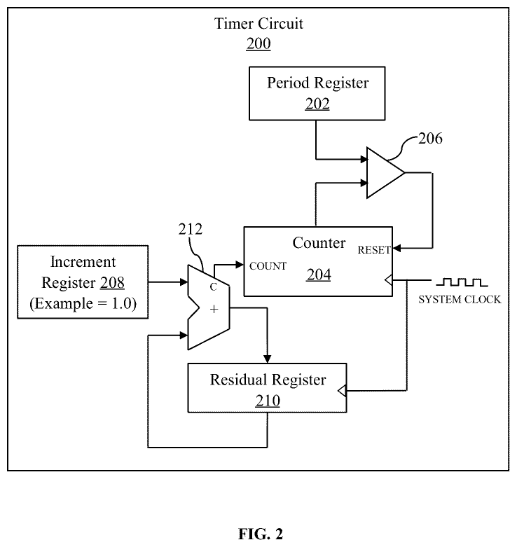

FIG. 2 illustrates an exemplary view of a timer circuit 200 having a shortest count period in a closed-loop control circuit in accordance with an implementation of the present disclosure. The timer circuit 200 includes a period register 202, a counter 204, and a comparator 206. The period register 202 is configured to hold a period value. The comparator 206 is configured to determine when the counter 204 reaches the period value. The timer circuit 200 is configured to adjust the frequency by adjusting an increment controlling the counter 204.

In an embodiment, the timer circuit 200 further includes an increment register 208 for holding the increment. An adjustment of the increment adjusts the frequency of the timer circuit 200. In embodiments, the increment register 208 is a variable increment register. The timer circuit 200 may be configured to receive an adjusted increment value by the adjusted increment value being written to the increment register 208. In an embodiment, the timer circuit 200 further includes a residual register 210, and an adding circuit 212. The residual register 210 is holding a residual. The adding circuit 212 is connected to the increment register 208 and the residual register 210. The adding circuit 212 is configured to (i) generate a sum by adding the increment to the residual; (ii) determine if the sum is less than an overflow value (OV), and if so output the sum to the residual register 210, and if not enable the counter 204 and output the remainder of the overflow value subtracted from the sum to the residual register 210.

In embodiments, the increment (i) is in the range larger than zero and equal to or less than the overflow value, i.e. (0<i<=OV). The residual register 210 may be configured to be reset when the counter 204 is reset. In an embodiment, the increment is decimal, the overflow value is 1, and the increment is binary. In an embodiment, the residual register 210 keeps track of the residual once the overflow value (i.e. once an integer has been reached).

The period register 202 may be set to the shortest count period desired for the operation of the closed-loop control circuit. The shortest count period may be achieved by setting the increment to 1. In embodiments, in every clock cycle, the increment is added to the counter 204. When the period value matches an integer of the counter 204, the counter 204 may reset to zero and starts again. In an embodiment, the increment may be called as a base and the residual may be called as a modifier. The resetting of the residual register 210 may be a subfunction for count up/count down function. In embodiments, the residual register 210 does not need to be zero depending on the final count period and accuracy. In an embodiment, in the up-down-count, the direction of the count changes at a period match event, and the counter 204 is decremented. In embodiments, the period register 202 is set to maximum to avoid sliding effects in the increment from the residual.

In an embodiment, the timer circuit 200 generates command signals from the integer of the counter 204 as like the existing solution. In embodiments, for increased time resolution of the command signals, the residual of the counter 204 can also be used for generating the compare/match events. In this case, the timer circuit 200 does not perform an exact compare/match of the period value with a count of the counter 204 since all decimal counts do not occur depending on the increment. Thus, the timer circuit 200 may perform a ‘greater than or equal’ or ‘less than or equal’ compare/match.

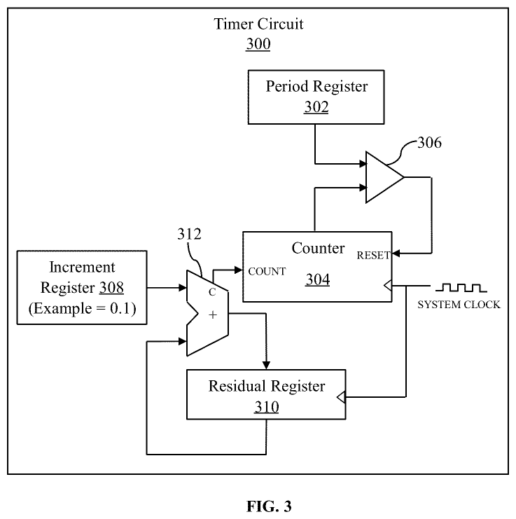

FIG. 3 illustrates an exemplary view of a timer circuit 300 having a longest count period in a closed-loop control circuit in accordance with an implementation of the present disclosure. The timer circuit 300 includes a period register 302, a counter 304, a comparator 306, an increment register 308, a residual register 310, and an adding circuit 312. The functions of the above parts are as described above. The period register 302 may be set to the longest count period desired for the operation of the closed-loop control circuit. The longest period is achieved with an increment that is less than 1.

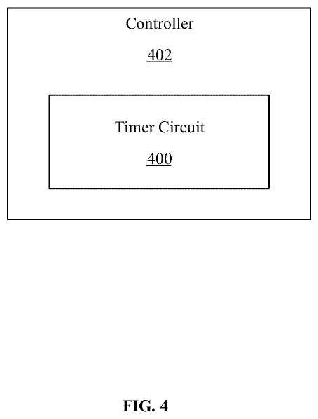

FIG. 4 is a block diagram of a controller 402 to vary a frequency of a control-loop in accordance with an implementation of the present disclosure. The controller 402 includes a timer circuit 400. The timer circuit 400 includes a period register, a counter, a comparator, an increment register, a residual register, and an adding circuit. The functions of the above parts are as described above.

The controller 402 reduces a delay in closed-loop operations of the closed-loop control circuit as a count period can be changed mid-period, thereby eliminating the need to wait until a next switching period. The controller 402 improves the dynamic performance of the closed-loop control circuit by reducing the latency/delay in the closed-loop operations. The controller 402 can be used for all control loop circuits where a frequency is to be controlled. The timer circuit 400 uses a variable increment register to generate the count period for resonant power topology circuits in the closed-loop operation. In an embodiment, the controller 402 is configured to determine that the frequency is to be adjusted and in response thereto adjusting the increment.

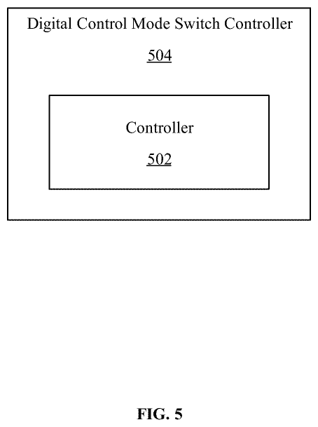

FIG. 5 is a block diagram of a digital control mode switch controller 504 to switch the mode of power supplies in accordance with an implementation of the present disclosure. The digital control mode switch controller 504 includes a controller 502 as described above in FIG. 4. The controller 502 includes a timer circuit. The timer circuit includes a period register, a counter, a comparator, an increment register, a residual register, and an adding circuit. The functions of the above parts are as described above.

The digital control mode switch controller 504 reduces a delay in closed-loop operations of the closed-loop control circuit as a count period can be changed mid-period, thereby eliminating the need to wait until a next counting/switching period. The digital control mode switch controller 504 improves the dynamic performance of the closed-loop control circuit by reducing the latency/delay in the closed-loop operations.

In embodiments, for generating a count period immediately for resonant power topologies in the closed-loop operation, the digital control mode switch controller 504 calculates a minimum counting/switching period for the resonant power topologies, according a system clock. The digital control mode switch controller 504 fixes a period value in the period register according to the minimum counting period. In an embodiment, the period value is used to trigger a counter reset event, where the counter is reset to zero. The digital control mode switch controller 504 calculates an actually counting period that is needed according to the system clock to determine the closed-loop control of the closed-loop control circuit. The digital control mode switch controller 504 calculates an integer and a residual of the incremental register according to the counting period that is needed from the closed-loop control. The digital control mode switch controller 504 writes the sum of the integer and the residual and updates the sum to the incremental register of the counter immediately. The counter works in every system clock and gets increased by the incremental register. In embodiments, the digital control mode switch controller 504 is a microcontroller unit, a processing unit, or a combination of both the microcontroller unit and the processing unit.

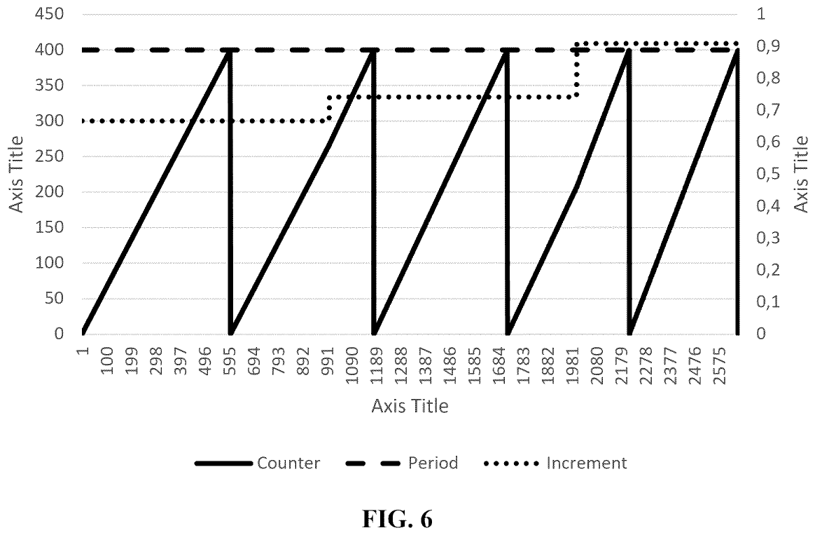

FIG. 6 is a graphical representation that shows an effect of a timer circuit that reduces a control loop delay of a closed-loop control circuit in accordance with an implementation of the present disclosure. The graphical representation depicts that the timer circuit reduces the control loop delay as a count period can be changed mid-period, thereby eliminating the need to wait until a next counting/switching period.

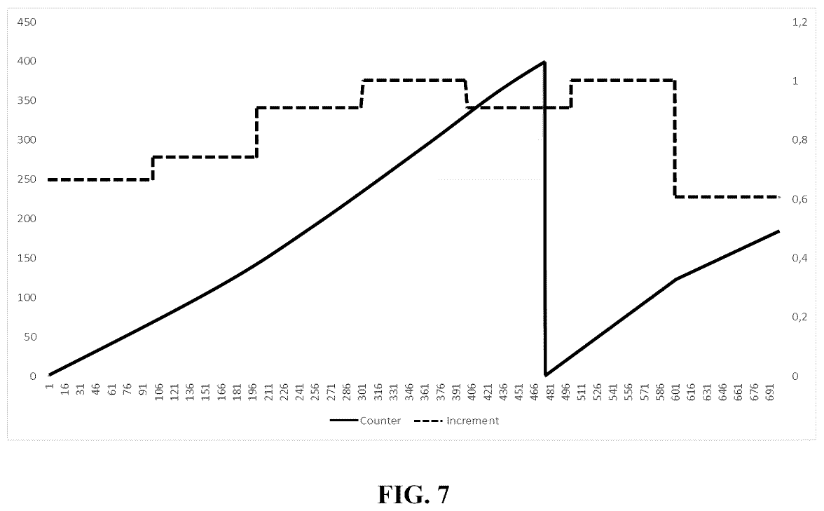

FIG. 7 is a graphical representation that shows an effect of a timer circuit that changes the increment multiple times during a count cycle in accordance with an implementation of the present disclosure. If the timer circuit changes the increment during the count cycle, it takes effect immediately without a risk of a corrupt period. The timer circuit allows for over sampling, i.e. the timer circuit can change the increment multiple times during the count cycle, which makes control command information also effective multiple times even between the counting/switching periods. Additionally, the timer circuit enables a change in the increment/decrement during a down-count part of an up-down-count.

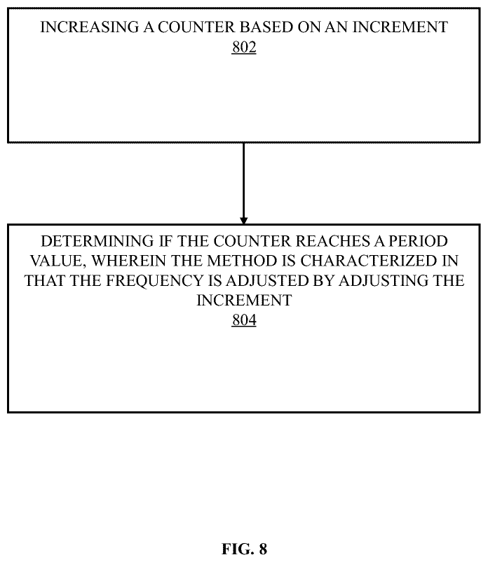

FIG. 8 is a flow diagram that illustrates a method for providing adjustable frequency timing in a closed-loop control circuit in accordance with an implementation of the present disclosure. At a step 802, a counter is increased based on an increment. At a step 804, it is determined if the counter reaches a period value. The frequency is adjusted by adjusting the increment.

The method reduces a delay in closed-loop operations of the closed-loop control circuit as a count period (i.e. a period time corresponds to the frequency) can be changed mid-period, thereby eliminating the need to wait until a next counting/switching period. The method eliminates the need for the period register to change the count period. The method reduces the delay incurred when varying the count period. The method improves the dynamic performance of the closed-loop control circuit by reducing the latency/delay in the closed-loop operations. The method controls the count period of a count cycle. The period value is fixed and the count period is controlled by varying the increment. If the method changes the increment during the count cycle, it takes effect immediately without a risk of corrupt period.

The method allows for over sampling, i.e. the method can change the increment multiple times during the count cycle, which makes control command information also effective multiple times even between the counting/switching periods. The method uses a variable increment register to generate the count period for resonant power topology circuits in the closed loop operations. The method can be used for all control loop circuits where a frequency is to be controlled.

In an embodiment, the method further includes holding a residual in a residual register. The method further includes generating a sum by adding the increment to the residual. The method further includes determining if the sum is less than an overflow value (OV), and if so outputting the sum to the residual register, and if not increasing the counter and outputting the remainder of the overflow value subtracted from the sum to the residual register.

In embodiments, the method further includes determining that the frequency is to be adjusted and in response thereto adjusting the increment.

It should be understood that the arrangement of components illustrated in the figures described are exemplary and that other arrangement may be possible. It should also be understood that the various system components (and means) defined by the claims, described below, and illustrated in the various block diagrams represent components in some systems configured according to the subject matter disclosed herein. For example, one or more of these system components (and means) may be realized, in whole or in part, by at least some of the components illustrated in the arrangements illustrated in the described figures.

In addition, while at least one of these components are implemented at least partially as an electronic hardware component, and therefore constitutes a machine, the other components may be implemented in software that when included in an execution environment constitutes a machine, hardware, or a combination of software and hardware.

Although the disclosure and its advantages have been described in detail, it should be understood that various changes, substitutions, and alterations can be made herein without departing from the spirit and scope of the disclosure as defined by the appended claims.

What is claimed is:

1. A timer circuit configured for providing adjustable frequency timing in a closed-loop control circuit, the timer circuit comprising:
a period register configured to hold a period value;
a counter; and
a comparator configured to determine when the counter reaches the period value;
wherein the timer circuit is configured to adjust the frequency by adjusting an increment controlling the counter.

2. The timer circuit according to claim 1, wherein the timer circuit further comprises an increment register for holding the increment, and wherein an adjustment of the increment adjusts the frequency of the timer circuit.

3. The timer circuit according to claim 2, wherein the timer circuit is configured to receive the adjusted increment value by the adjusted increment value being written to the increment register.

4. The timer circuit according to claim 2, wherein the timer circuit further comprises:
a residual register for holding a residual; and
an adding circuit connected to the increment register, and the residual register, and wherein the adding circuit is configured to:
generate a sum by adding the increment to the residual;
output the sum to the residual register in response to determining that the sum is less than an overflow value, or
enable the counter in response to determining that the sum is not less than the overflow value, and
output a remainder of the overflow value subtracted from the sum to the residual register.

5. The timer circuit according to claim 4, wherein the increment is in a range larger than zero and equal to or less than the overflow value (OV).

6. The timer circuit according to claim 4, wherein the residual register is configured to be reset when the counter is reset.

7. The timer circuit according to claim 1, wherein the increment is a decimal.

8. The timer circuit according to claim 4, wherein the overflow value is 1.

9. The timer circuit according to claim 1, wherein the increment is binary.

10. A controller configured to vary a frequency of a control-loop, the controller comprising a timer circuit which comprises:
a period register configured to hold a period value;
a counter; and
a comparator configured to determine when the counter reaches the period value;
wherein the timer circuit is configured to adjust the frequency by adjusting an increment controlling the counter.

11. The controller according to claim 10, wherein the controller is configured to determine that the frequency is to be adjusted and in response thereto adjusting the increment.

12. A method for providing adjustable frequency timing in a closed-loop control circuit, wherein the method comprises:
increasing a counter based on an increment; and
determining if the counter reaches a period value, wherein the frequency is adjusted by adjusting the increment.

13. The method of claim 12, wherein the method further comprises:
holding a residual in a residual register;
generating a sum by adding the increment to the residual;
outputting the sum to the residual register in response to determining that the sum is less than an overflow value, or
increasing the counter in response to determining that the sum is not less than the overflow value, and
outputting a remainder of the overflow value subtracted from the sum to the residual register.

14. The method of claim 12, wherein the method further comprises determining that the frequency is to be adjusted and in response thereto adjusting the increment.
